(19) United States
(12) Patent Application Publication
(10) Pub. No.: US 2026/0195227 A1
(43) Pub. Date: Jul. 9, 2026

(54) FLEXIBLE SYSTOLIC IN-MEMORY ARRAY TESTING DEVICE AND CONTROL METHOD THEREOF

(71) Applicant: HUAZHONG UNIVERSITY OF SCIENCE AND TECHNOLOGY, Hubei (CN)

(72) Inventors: Xingsheng Wang, Hubei (CN); Fan Yang, Hubei (CN); Haozhe Lou, Hubei (CN); Nan Li, Hubei (CN); Letian Wang, Hubei (CN); Xiangshui MIAO, Hubei (CN)

(73) Assignee: HUAZHONG UNIVERSITY OF SCIENCE AND TECHNOLOGY, Hubei (CN)

(21) Appl. No.: 19/439,423

(22) Filed: Jan. 4, 2026

(30) Foreign Application Priority Data
Jan. 7, 2025 (CN) 202510022844.4

(51) Int. Cl. G06F 11/27; G11C 29/12

(52) U.S. Cl. CPC G06F 11/27; G11C 29/12005

(57) ABSTRACT

A flexible systolic in-memory array testing device including a sub-board array is provided. Each of a plurality of sub-boards in the sub-board array includes a chip socket, a digital-to-analog conversion module, a driving module, a differential readout module, an analog-to-digital conversion module, a shift and accumulation module, and first to fourth bidirectional ports. The chip socket is placed with an in-memory array chip. The digital-to-analog conversion module converts an input vector into a voltage signal. The driving module provides a driving current. The differential readout module includes two inverting amplifier circuits and one adder-subtractor circuit, performs differential sampling on a result of the in-memory chip, and then performs outputting to the analog-to-digital conversion module for analog-to-digital conversion. The shift and accumulation module then performs shift accumulation on an analog-to-digital conversion result and digital signals from other sub-boards to obtain a result vector.

### CROSS-REFERENCE TO RELATED APPLICATION

This application claims the priority benefit of China application serial no. 202510022844.4, filed on January 7, 2025. The entirety of the above-mentioned patent application is hereby incorporated by reference herein and made a part of this specification.

### BACKGROUND

### Technical Field

The disclosure belongs to the technical field related to microelectronics, and more specifically, relates to a flexible systolic in-memory array testing device and a control method thereof.

### Description of Related Art

With the rapid development of artificial intelligence technology, especially the widespread applications of deep learning algorithms in fields such as autonomous driving, industrial control, and intelligent monitoring, growing demands have been placed on the performance and reliability of edge computing hardware. These devices need to achieve efficient data processing and fast intelligent decision-making under limited energy and space conditions. The computing-in-memory (CIM) technology, represented by memristors, has become one of the key technologies for addressing AI computing power demands due to its significant advantages in providing high computing power, high energy efficiency, and low latency.

A memristor, as a non-volatile memory device, possesses dual functions of storage and computation. Its unique physical characteristics has demonstrated considerable potential in in-memory computing applications. By placing data storage and computation at the same location, a memristor is able to significantly reduce data transmission distance, lower power consumption, and improve computational efficiency. Therefore, memristors typically serve as core components of CIM technology, and their unique data storage and processing capabilities provide possibilities for achieving AI hardware with high computing power, high energy efficiency, and low latency.

Although memristor technology has exhibited obvious advantages in theory, designing and fabricating a full on-chip SOC chip based on in-memory computing in practical applications still faces many challenges. For instance, to detect the circuit characteristics of memristor arrays (such as conductivity and durability) and to implement the application of memristors in deep learning algorithms, extensive preliminary exploration and verification of memristor arrays are required. At present, the testing and verification work of memristor arrays mainly relies on simulation models, which usually cannot satisfy the performance evaluation needs of memristor arrays under actual working conditions, especially in large-scale integration and high-speed computing environments. Further, existing test systems often lack flexibility and are difficult to adapt to constantly changing technological developments and application needs.

At present, there is a lack of an effective circuit system for testing and architecture verification of non-volatile memory array chips represented by memristors. Therefore, how to design a circuit testing device based on FPGA to test memristor array chips and then achieve digital logic verification of chip architecture and algorithm deployment, has become a key issue in promoting the practical applications of memristor technology.

Therefore, designing a testing device with flexibility to test in-memory array chips to achieve digital logic verification of chip architecture and algorithm deployment, is a key issue in promoting the practical applications of memristor technology.

### SUMMARY

In view of the above defects or improvement needs of the related art, the disclosure provides a flexible systolic in-memory array testing device and a control method thereof with an aim to test an in-memory chip.

To achieve the above, the disclosure provides a flexible systolic in-memory array testing device including a sub-board array composed of a plurality of sub-boards. Each of the sub-boards includes a chip socket, a digital-to-analog conversion module, a driving module, a differential readout module, an analog-to-digital conversion module, a shift and accumulation module, and first to fourth bidirectional ports.

The chip socket is configured to be placed with an in-memory array chip that performs a matrix operation with an input vector.

Bidirectional transmission of an input vector can be performed between the first bidirectional port and the second bidirectional port of a previous sub-board in a same row and between the first bidirectional port and the second bidirectional port of its own sub-board.

The digital-to-analog conversion module is configured to obtain the input vector from the first bidirectional port and convert it into a voltage signal, and the driving module is configured to connect the voltage signal to the chip and provide a driving current.

Bidirectional transmission of a result vector can be performed between the third bidirectional port and the fourth bidirectional port of a foregoing sub-board in a same column and between the third bidirectional port and the shift and accumulation module of itself, and bidirectional transmission of the result vector can be performed between the fourth bidirectional port and the shift and accumulation module.

The differential readout module includes two inverting amplifier circuits and one adder-subtractor circuit. Non-inverting input terminals of the two inverting amplifier circuits sample output currents of two adjacent columns in the chip, inverting input terminals are applied with clamping voltages, and output terminals are connected to the adder-subtractor circuit for differential calculation and then perform outputting to the analog-to-digital conversion module for analog-to-digital conversion. The shift and accumulation module is configured to perform shift accumulation on an analog-to-digital conversion result and a digital signal from the third bidirectional port or the fourth bidirectional port to achieve aggregation and obtain the result vector.

Optionally, a resistor connected between the inverting input terminal and the output terminal of each of the inverting amplifier circuits is an adjustable resistor.

Optionally, the clamping voltage applied to each of the inverting amplifier circuits has a value range of 0.4V to 0.6V.

Optionally, the driving module is a voltage follower constructed by an operational amplifier.

Optionally, the driving current provided by the driving module is 40mA to 60mA.

Optionally, the in-memory array chip is a non-volatile memory array chip.

Optionally, one sub-board can accommodate two chips, and matrix expansion is achieved through the two chips.

Optionally, the device further includes an FPGA programmable logic array for implementing data scheduling and control.

The disclosure further provides a control method for a flexible systolic in-memory array testing device, and the testing device is the testing device as described in any one of the above. The control method includes the following steps.

N groups of input vectors to be input into the sub-board array are obtained. One group of input vectors corresponds to one row of sub-boards, and N is the number of rows of the sub-board array.

Data is scheduled and controlled data according to a set systolic direction The systolic direction includes a row systolic direction of an input vector between sub-boards in a same row and a column systolic direction of a result vector between sub-boards in a same column. The scheduling and controlling data includes the following step.

The input vector is controlled to be transmitted sequentially from a previous sub-board to a next sub-board in a pipeline mode in the row systolic direction through the first bidirectional port and the second bidirectional port, and the result vector is controlled to be transmitted sequentially from a foregoing sub-board to a next following sub-board in a pipeline mode in the column systolic direction through the third bidirectional port and the fourth bidirectional port. Transmission time of the input vector between adjacent sub-boards and processing time for the sub-board to receive the input vector and obtain the result vector are both one systolic cycle. The sub-board acquires a new input vector in each systolic cycle to complete the matrix operation and acquires the result vectors from other sub-boards to perform shift accumulation to obtain a new result vector.

Optionally, the systolic direction is any one of the following settings:

In setting one, the input vector systolically moves rightward, and the result vector moves systolically downward.

In setting two, the input vector systolically moves rightward, and the result vector moves systolically upward.

In setting three, the input vector systolically moves leftward, and the result vector moves systolically upward.

In setting four, the input vector systolically moves leftward, and the result vector moves systolically downward.

The leftward and rightward are two opposite directions in which rows extend in the sub-board array, and the upward and downward are two opposite directions in which columns extend in the sub-board array.

Overall, compared with the related art, the technical solutions conceived by the disclosure mainly have the following beneficial effects.

1. In the disclosure, the testing device is provided with a sub-board array, and each sub-board is provided with a chip socket, a digital-to-analog conversion module, a driving module, a differential readout module, an analog-to-digital conversion module, a shift and accumulation module, and first to fourth bidirectional ports. After connecting the memory chip under test, a matrix operation between the in-memory chip and the input vector may be implemented, and testing of the memory chip is thus implemented.

2. In the disclosure, the sub-board array is arranged, and signal transmission between the sub-board array is implemented through ports. The input vector can be transmitted in the row direction of the sub-board array, and the result vector obtained by each sub-board can be transmitted in the column direction of the sub-board array. The result vector of each sub-board can be gradually shifted and accumulated in the column direction. Therefore, calculation of different bit widths can be performed as needed, and improved flexibility is thus provided. Further, the ports are configured as bidirectional ports, and bidirectional data paths are arranged within the sub-boards and between the sub-boards, allowing selection of systolic directions as needed, and the flexibility of the device is thereby further improved. Moreover, based on the testing device in the disclosure, calculation of different precisions can be implemented, and multi-bit-width fusion can also be implemented. Therefore, flexible applications are provided to perform different operations. In addition, the differential readout module implements storage and operation of positive and negative weights of the neural network through the design of the inverting amplifier readout and the adder-subtractor circuit, which is fully compatible with neural network calculation.

3. Optionally, the resistor connected between the inverting input terminal and the output terminal of the inverting amplifier circuit is an adjustable resistor. In array chips with different resistance state distributions, the output current ranges vary greatly. By arranging different feedback resistors, current sampling under different resistance state distributions is achieved, and the flexibility of the testing device is thus further enhanced.

### BRIEF DESCRIPTION OF THE DRAWINGS

FIG. 1 is a structural schematic diagram of an in-memory array testing device in an embodiment of the disclosure.

FIG. 2 is a structural schematic diagram of a sub-board in an embodiment of the disclosure.

FIG. 3 is a structural diagram of a 1T1R array of a chip crossbar in an embodiment of the disclosure.

FIG. 4A and FIG. 4B are used to demonstrate a structural schematic diagram of a differential readout module in an embodiment of the disclosure, wherein FIG. 4A is a composition diagram of the differential readout module, and FIG. 4B is a schematic diagram of its adjustable resistor.

FIG. 5 is a schematic structural diagram of a portion participating in a matrix operation within a sub-board in an embodiment of the disclosure.

FIG. 6 is a structural schematic diagram of a digital-to-analog conversion module and a driving module in an embodiment of the disclosure.

FIG. 7 is a systolic principle diagram in an embodiment of the disclosure.

FIG. 8 is a schematic diagram of performing operations with different precisions in an embodiment of the disclosure.

FIG. 9 is a schematic diagram of performing multi-bit-width fusion in an embodiment of the disclosure.

FIG. 10 is a schematic diagram of computational acceleration of a neural network in an embodiment of the disclosure.

### DESCRIPTION OF THE EMBODIMENTS

In order to make the objectives, technical solutions, and advantages of the disclosure more clearly understood, the disclosure is further described in detail below with reference to the accompanying drawings and embodiments. It should be understood that the specific embodiments described herein are merely used to explain the disclosure and are not intended to limit the disclosure. Furthermore, the technical features involved in the various embodiments of the disclosure described below may be combined with each other as long as they do not conflict with each other.

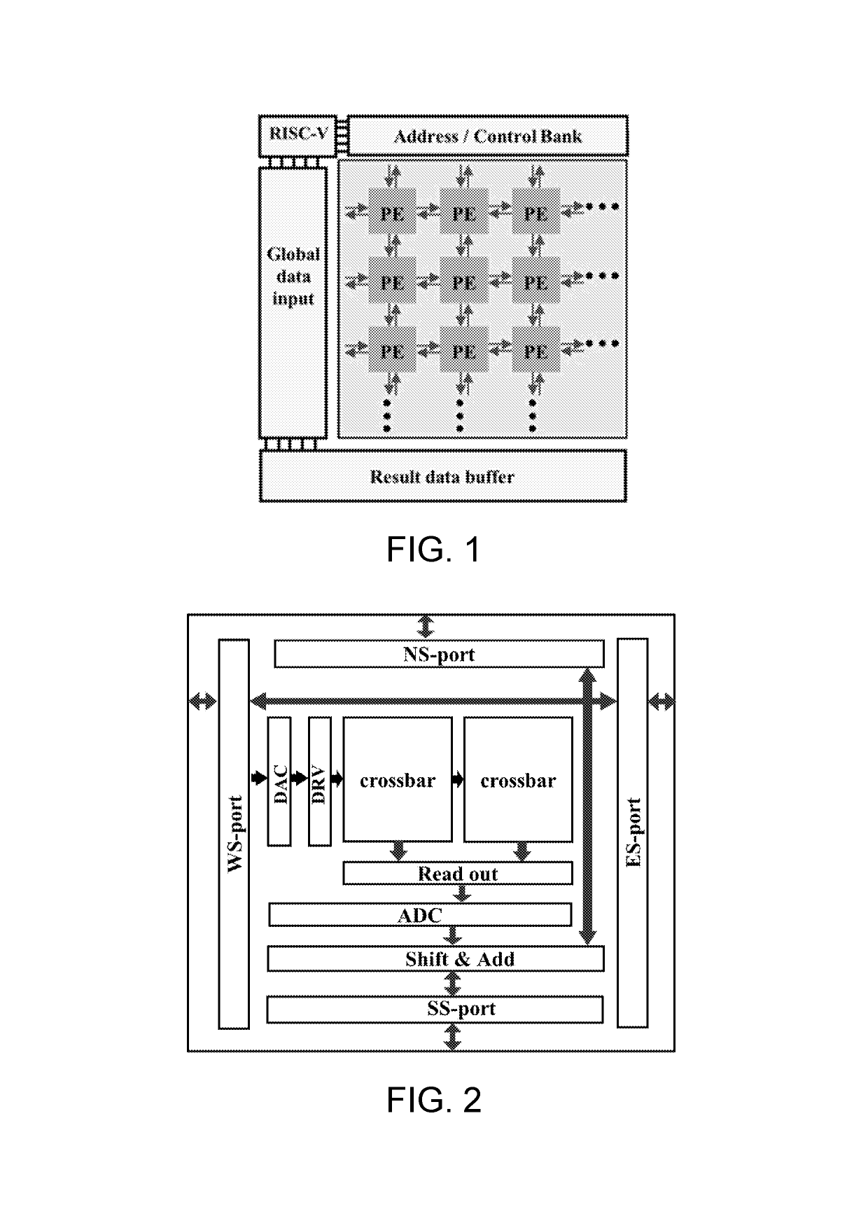

The disclosure provides a flexible systolic in-memory array testing device. FIG. 1 is a structural schematic diagram of an in-memory array testing device in an embodiment of the disclosure. FIG. 2 is a structural schematic diagram of a sub-board in an embodiment of the disclosure.

Referring to FIG. 1 and FIG. 2, the in-memory array testing device includes a motherboard composed of a sub-board array formed by a plurality of sub-boards PE. Each of the sub-boards PE includes a chip socket, a digital-to-analog conversion module DAC, a driving module DRV, a differential readout module Read out, an analog-to-digital conversion module ADC, a shift and accumulation module Shift&Add, a first bidirectional port WS-port, a second bidirectional port ES-port, a third bidirectional port NS-port, and a fourth bidirectional port SS-port.

The chip socket is configured to be placed with an in-memory array chip crossbar that performs a matrix operation with an input vector. Each node in the in-memory array chip crossbar is used to store weight information. The input vector is defined as a vector A, the weight information stored in the in-memory array chip crossbar is a matrix W, and the operation performed by the sub-board is: C=A*W, where C is a result vector. Specifically, the in-memory array chip is a non-volatile memory array chip. When the in-memory array is used for a deep learning model, it is configured to store weights of a specific layer in the deep learning model. These weights are fixed after model training is completed, no longer change after the model is deployed to hardware, and are tested through the testing device provided by the disclosure.

Bidirectional transmission of the input vector A can be performed between the first bidirectional port WS-port and the second bidirectional port ES-port of a previous sub-board in a same row and between the first bidirectional port WS-port and the second bidirectional port ES- port of its own sub-board.

The digital-to-analog conversion module DAC is configured to obtain the input vector A from the first bidirectional port WS-port and convert it to a voltage signal.

The driving module DRV is configured to connect the voltage signal to the chip crossbar and provide driving current.

Bidirectional transmission of a result vector C can be performed between the third bidirectional port NS-port and the fourth bidirectional port SS-port of a foregoing sub-board in a same column and between the third bidirectional port NS-port and the shift and accumulation module Shift&Add of itself, and bidirectional transmission of the result vector C can be performed between the fourth bidirectional port SS-port and the shift and accumulation module Shift&Add.

The differential readout module Read out is configured to read current information of every two adjacent columns of the chip crossbar and convert it into a differential voltage for storage.

The analog-to-digital conversion module ADC performs analog-to-digital conversion on the differential voltage.

The shift and accumulation module Shift&Add is configured to perform shift accumulation on an analog-to-digital conversion result and a digital signal from the third bidirectional port NS-port or the fourth bidirectional port SS-port to achieve aggregation and obtain the result vector C. For instance, when matrix multiplication is performed, each PE calculates a partial product, and a shifter and an adder add these partial products in the correct order and position, so as to obtain the final matrix multiplication result. This operation is performed in parallel, where the output of each PE immediately participates in the final accumulation, so that efficient matrix multiplication computation is achieved.

Since the WS-port and the ES-port are bidirectional ports, this design may implement leftward systolic movement and rightward systolic movement of the input vector A. Further, the NS-port and the SS-port are bidirectional ports as well, this design may implement upward systolic movement and downward systolic movement of the result vector C, allowing the systolic array architecture to have improved flexibility.

Therefore, the testing device of the disclosure has a total of four systolic directions. During specific testing, any one of the following systolic settings may be selected according to needs:

setting one: the input vector A systolically moves rightward, and the result vector C systolically moves downward;

setting two: the input vector A systolically moves rightward, and the result vector C systolically moves upward;

setting three: the input vector A systolically moves leftward, and the result vector C systolically moves upward; and

setting four: the input vector A systolically moves leftward, and the result vector C systolically moves downward.

Herein, the leftward and rightward are two opposite directions in which rows extend in the sub-board array, and the upward and downward are two opposite directions in which columns extend in the sub-board array.

Taking the example of the input vector A systolically moving rightward and the result vector C systolically moving downward, the first bidirectional port WS-port transmits the input vector A to the DAC, which is loaded onto the array chip crossbar through the DRV. The differential readout module Read out collects a current operation result, converts it to the differential voltage, and then delivers it to the ADC for quantization encoding. The ADC aggregates the encoded data through the shift and accumulation module Shift&Add with the result vector from a foregoing sub-board in a column direction, and then transmits an obtained new result vector to the fourth bidirectional port SS-port, which is transmitted by the fourth bidirectional port SS-port to a next sub-board in the column direction for aggregation, and the downward systolic movement of the result vector is thus achieved. The input vector A is transmitted through the first bidirectional port WS-port and the second bidirectional port ES-port to a next sub-board in a row direction, and the leftward systolic movement of the input vector is thus achieved. The entire process completes the process of conversion of data from the digital domain to the analog domain and then back to the digital domain after matrix operations in the analog domain.

If the input vector A systolically moves leftward, the input vector A is directly transmitted from the ES-port to the WS-port for a matrix operation circuit of the left sub-board.

If the result vector C systolically moves upward, the result vector C is directly transmitted to the NS-port and enters the shift accumulation calculation of the upper-side sub-board.

In the disclosure, a sub-board array is provided, and signal transmission in the sub-board array is implemented through ports. The input vector may be transmitted in the row direction of the sub-board array, and the result vector obtained by each sub-board may be transmitted in the column direction of the sub-board array. The result vector of each sub-board may be gradually shifted and accumulated in the column direction. Therefore, calculation of different bit widths may be performed as needed, and improved flexibility is thus provided. Further, the ports are configured as bidirectional ports, and bidirectional data paths are provided within the sub-boards and between the sub-boards, allowing selection of different systolic directions as needed, and the flexibility of the device is thus further improved.

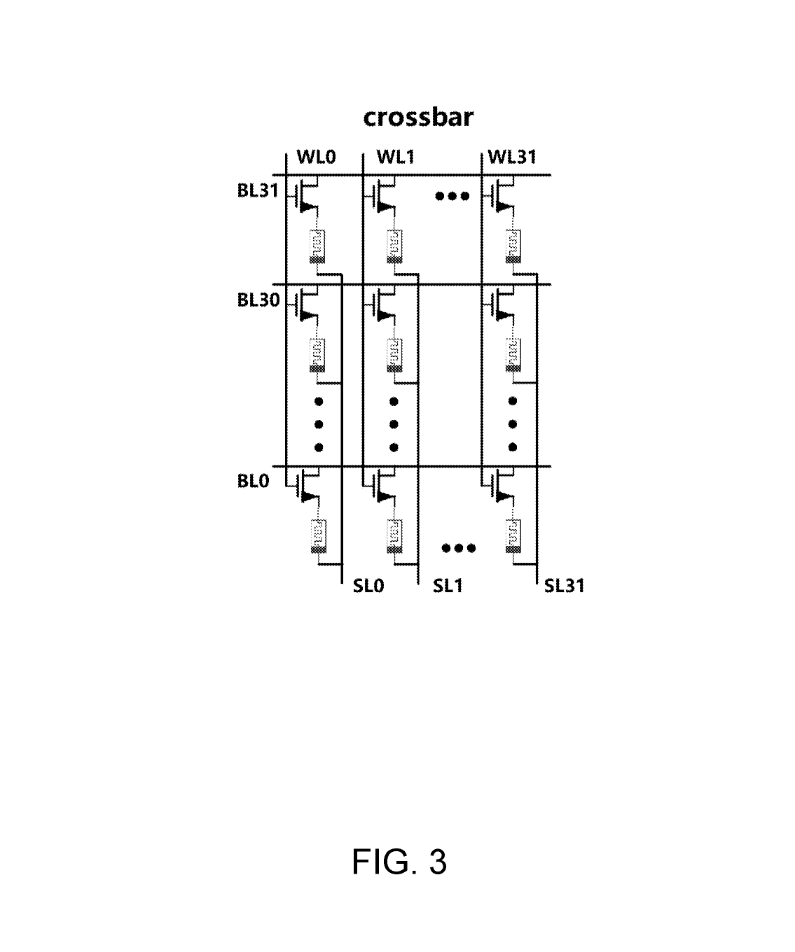

FIG. 3 shows a 1T1R array structure diagram of the chip crossbar in an embodiment of the disclosure, where a word line WL is parallel to a signal line SL, and a bit line BL is perpendicular to the WL and the SL. A voltage is applied to the BL, and then a control module sends a pulse to turn on the WL for a matrix operation, and an SL output current is sampled by the differential readout module.

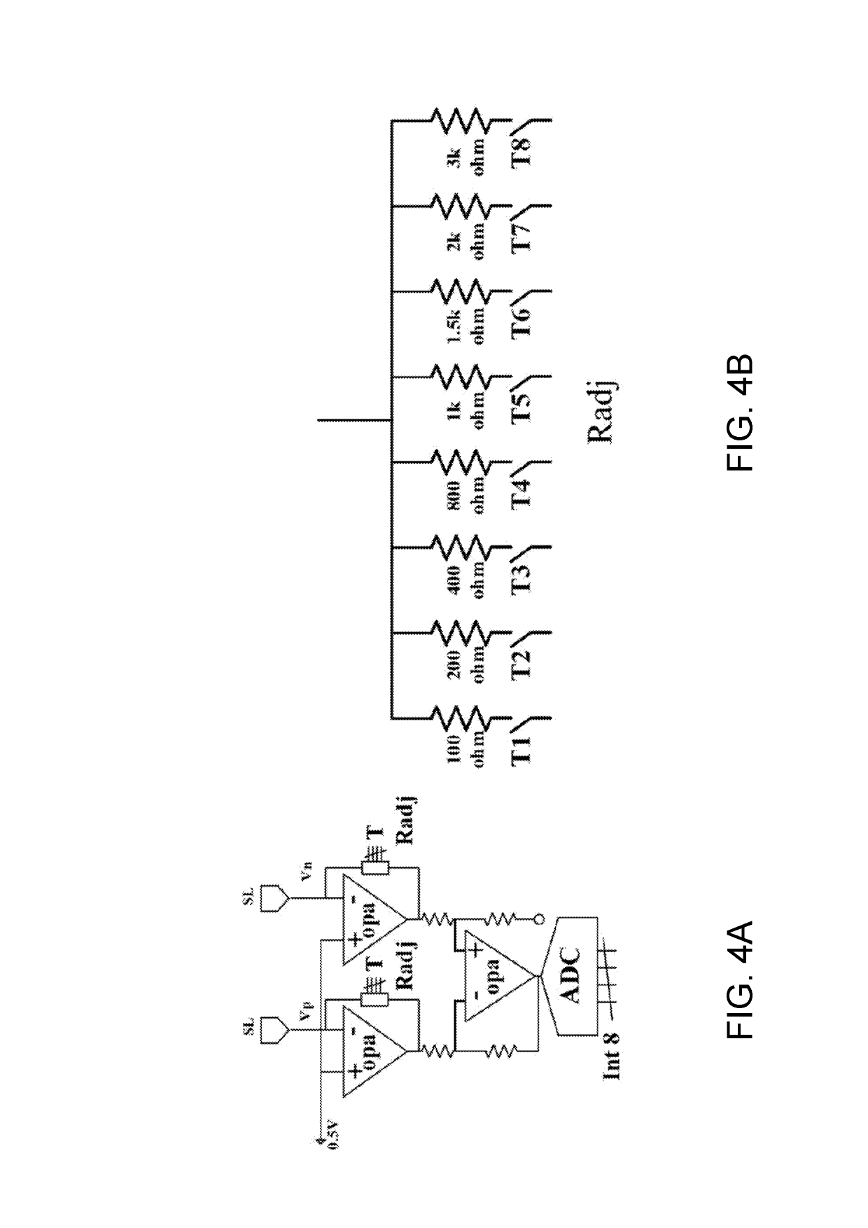

As shown in FIG. 4A and FIG. 4B, which are used to demonstrate a structural schematic diagram of the differential readout module in an embodiment of the disclosure. The differential readout module includes two inverting amplifier circuits and one adder-subtractor circuit. Non- inverting input terminals of the two inverting amplifier circuits sample output currents of two adjacent columns in the chip, inverting input terminals are applied with clamping voltages, and output terminals are connected to the adder-subtractor circuit for differential calculation and then perform outputting to the analog-to-digital conversion module.

Specifically, the clamping voltage connected to each of the inverting amplifier circuits has a value range of 0.4V to 0.6V, for example, it may be 0.5V.

In the design of the above differential readout module, voltage clamping and current sampling are performed on the output terminal through the inverting amplifier circuit, and then differential readout of two adjacent columns of the in-memory array is performed through the adder-subtractor circuit. The above readout circuit design scheme is fully compatible with neural network computation. The details are as follows: the weights of a neural network have positive and negative distribution, but memristors in a memristor array may only store conductance values. Two adjacent memristors serving as a differential pair, and the storage of positive and negative weights may thus be implemented. For instance, a memristor may store a low conductance state and a high conductance state, representing 0 and 1 respectively. When the positive-phase memristor in the differential pair stores the high conductance state 1 and the negative-phase memristor stores the low conductance state 0, the represented neural network weight is 1. When the positive-phase memristor in the differential pair stores the low conductance state 0 and the negative-phase memristor stores the low conductance state 0, the represented neural network weight is 0. When the positive-phase memristor in the differential pair stores the low conductance state 0 and the negative-phase memristor stores the high conductance state 1, the represented neural network weight is -1. The inverting amplifier converts the readout result of each column into a voltage, which is then input to the adder-subtractor circuit. A positive column readout voltage Vp is input to an addition terminal of the adder-subtractor circuit, and a negative column readout voltage Vn is input to a subtraction terminal of the adder-subtractor circuit, and a result Vout is: Vout=Vp-Vn.

Therefore, through the inverting amplifier readout and the adder-subtractor circuit, the storage and computation of the positive and negative weights in neural network are achieved.

In a specific embodiment, a resistor connected between the inverting input terminal and the output terminal of each inverting amplifier circuit is an adjustable resistor R_{adj}. For instance, R_{adj} has 8 selection switches, and different sampling resistor levels may be selected according to resistance state control of the array chip, which are 100Ω, 200Ω, 400Ω, 800Ω, 1kΩ, 1.5kΩ, 2kΩ, and 3kΩ. The adjustable resistor R_{adj} may be implemented using a programmable resistor string, which may be controlled and adjusted by the FPGA. In array chips with different resistance state distributions, output current ranges vary greatly, and current sampling under different resistance state distributions may be achieved by arrangement of different feedback resistors. Two adjacent columns serve as a differential pair to store information, and the voltages read out through the two inverting amplifier circuits are input to the adder-subtractor circuit for differential readout. Finally, the adder-subtractor circuit subtracts the two readout voltages and outputs the result to the ADC for sampling and quantization.

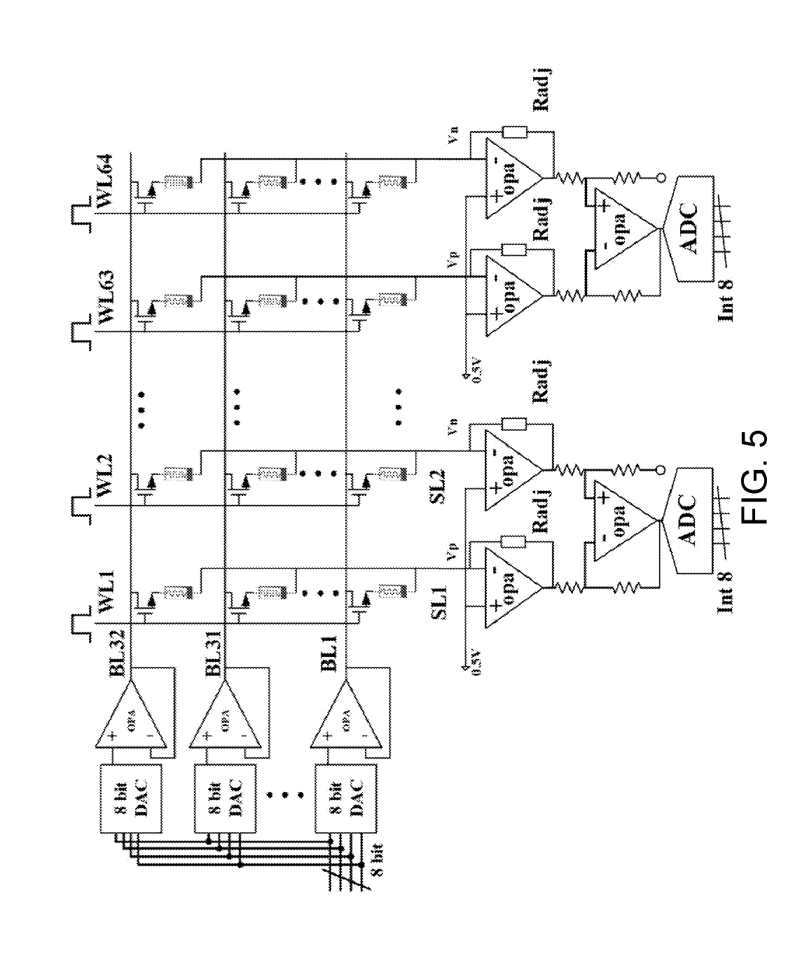

As shown in FIG. 5, which is a schematic structural diagram of a portion participating in a matrix operation within a sub-board in an embodiment of the disclosure. The input vector A with a data type of 8 bit is converted into a voltage signal of 0 V to 0.3 V through the digital-to-analog conversion module and loaded into a memristor array. According to Kirchhoff's law I=V·G, a matrix multiplication operation is performed, and the calculated analog current vector result is input to the differential readout module and the ADC. The ADC converts the current vector into a signed 8-bit result vector C. The specific matrix operation formula is: C=A·W.

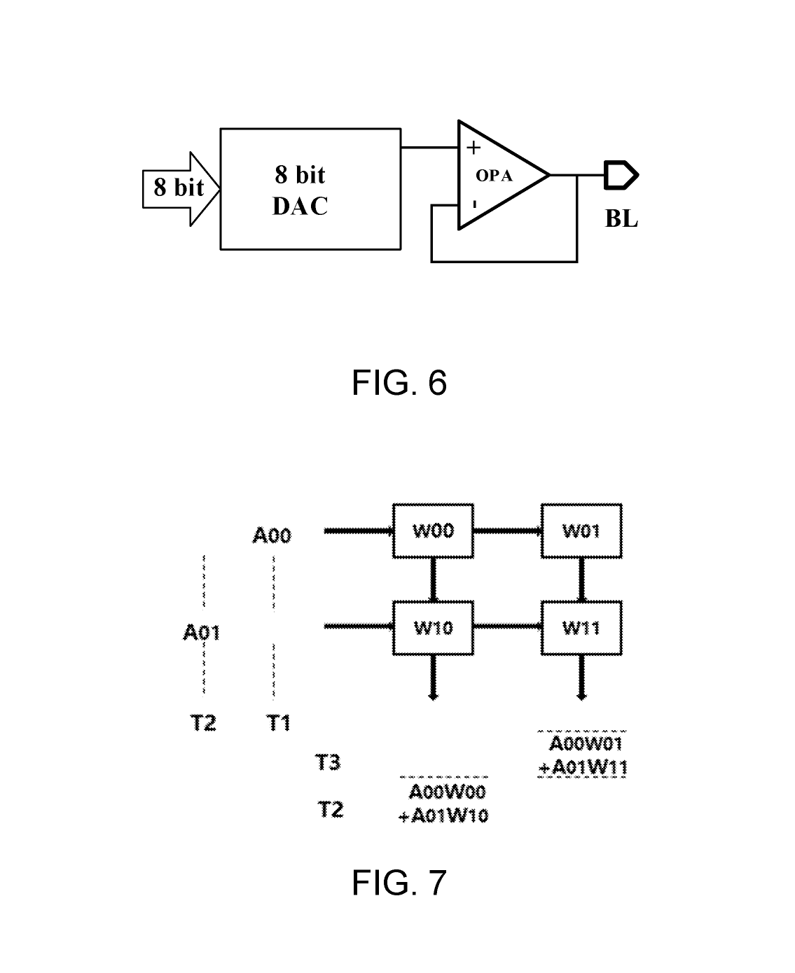

As shown in FIG. 6, which is a schematic structural diagram of a digital-to-analog conversion module and a driving module in an embodiment of the disclosure. The digital-to-analog conversion module DAC converts the input vector A into a voltage vector and then loads the input vector A onto the memristor array chip through the driving module. The driving module is a voltage follower constructed by an operational amplifier. The operational amplifier adopts class AB output and provides a driving current of 40mA to 60mA, for example, may be 50mA, which is sufficient for testing various non-volatile memory array chips. In the disclosure, the driving module is arranged for the purpose of providing a driving current to drive the in-memory array for testing.

In an embodiment, the testing device has an FPGA circuit, and data scheduling and control are implemented based on the FPGA circuit. When it is necessary to deploy different deep learning models or adjust parameters of existing models, the new needs may be accommodated by modifying the configuration of the FPGA without replacing hardware. This flexibility enables the testing device to adapt to constantly changing computational tasks and technological development. Specifically, the first to fourth bidirectional ports may all be bidirectional data transmission ports implemented by the FPGA, the FPGA may implement leftward systolic movement or rightward systolic movement of the input vector A, and the FPGA may implement upward systolic movement or downward systolic movement of the result vector C. Specifically, the DAC and the ADC may also be directly connected to the FPGA, and the FPGA is used for scheduling and controlling the input vector A and the result vector C. In the in-memory array, gates of gated transistors in the same column are connected together as a word line WL control terminal, and all WLs are directly connected to the FPGA for control. After the voltage vector in the memristor array is loaded, the WL is turned on through a control pulse of the FPGA to perform analog matrix multiplication. Further, the RISC-V, address control, data cache, and the like in the testing device may all be implemented and verified by the FPGA.

Correspondingly, the disclosure further provides a control method for a flexible systolic in-memory array testing device, and the control method includes the following steps.

N groups of input vectors to be input into the sub-board array are obtained. One group of input vectors corresponds to one row of sub-boards, and N is the number of rows of the sub-board array.

Data is scheduling and controlled according to a set systolic direction. The systolic direction includes a row systolic direction of input vectors between sub-boards in the same row and a column systolic direction of result vectors between sub-boards in the same column. The scheduling and controlling data includes the following step.

The input vector is controlled to be transmitted sequentially from a previous sub-board to a next sub-board in a pipeline mode in the row systolic direction through the first bidirectional port and the second bidirectional port, and the result vector is controlled to be transmitted sequentially from a foregoing sub-board to a next following sub-board in a pipeline mode in the column systolic direction through the third bidirectional port and the fourth bidirectional port. Transmission time of the input vector between adjacent sub-boards and processing time for a sub-board to receive the input vector and obtain the result vector are both one systolic cycle, and the sub-board acquires a new input vector in each systolic cycle to complete the matrix operation and acquires result vectors from other sub-boards to perform shift accumulation to obtain a new result vector.

Overall, data flow in the systolic array is pipelined, which means that each PE may immediately start processing the next group of data after finishing processing the current input data. In this immediate transfer mechanism, the stagnation time of data between Pes is significantly reduced because each PE is continuously receiving new input and producing output, rather than waiting for the entire array to complete all computation.

Specifically, when the test is performed, the test steps include the following.

A memristor array chip to be tested is placed on the chip socket in the testing device.

The input vector A is loaded to the BL terminal in the memristor chip through the FPGA.

A control pulse is sent through a control pin of the FPGA to turn on all WLs, and the memristor array chip performs an analog matrix operation.

The readout circuit reads out the current of the array and converts it to a voltage, which is then sampled and converted by the ADC.

A control port of the FPGA receives the result vector from the previous sub-board and performs shift accumulation to obtain a new result vector.

As shown in FIG. 7, which is a systolic principle diagram in an embodiment of the disclosure. Assuming there are 2 groups of input vectors, namely A00 and A01, the motherboard is a 2*2 sub-board array, and the stored weights are W00, W01, W10, and W11. A00 is input to the first row of sub-boards, and A01 is input to the second row of sub-boards. According to the data scheduling rules:

At T1, the sub-board W00 is input with A00, the sub-board W00 performs calculation to obtain a result vector A00W00, and both the sub-board W10 and the sub-board W11 have no output.

At T2, A00 is transmitted from the sub-board W00 to the sub-board W01, the sub-board W01 performs calculation and obtains a result vector A00W01, A01 is input to the sub-board W10, the sub-board W10 outputs a result vector A00W00+ A01W10, and the sub-board W11 has no output.

At T3, A01 is transmitted from the sub-board W10 to the sub-board W11, the sub-board W11 outputs a result vector A00W01+ A01 W11, and the sub-board W10 has no output.

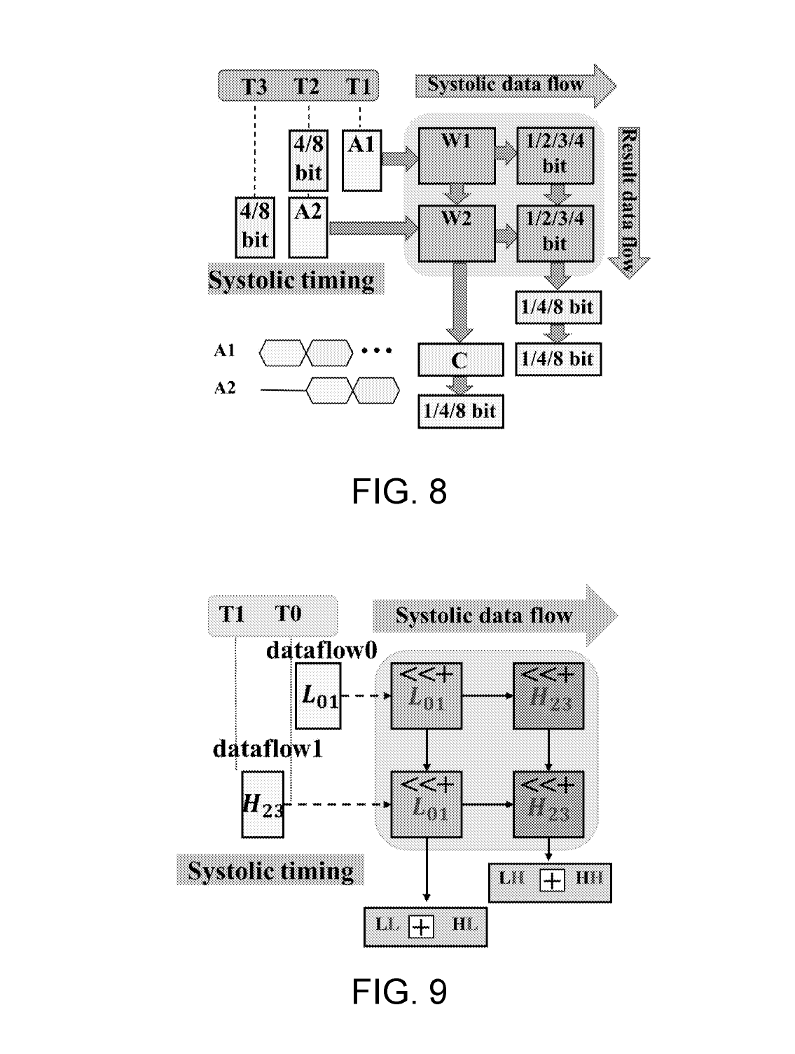

Based on the testing device, operations of different precisions may be implemented. As shown in FIG. 8, which is a schematic diagram of performing operations with different precisions in an embodiment of the disclosure. The input vector A has three-bit widths of 1 bit, 4 bits, and 8 bits. The PE in the architecture may store data of four-bit width types of 1 bit, 2 bits, 3 bits, and 4 bits. The ADC in the PE has 1-bit, 4-bit, and 8-bit operating modes and therefore may directly output data of three-bit width types. By configuring the data type in the PE, matrix operations of different precisions may be implemented. For instance, in a high precision mode, the input vector A is configured with 8-bit bit width, the memristor array in the PE stores weight data of 4-bit bit width, and the ADC uses 8 bits for sampling. In a low precision mode, the input vector A is configured with 1-bit bit width, the memristor array in the PE stores weight data of 1-bit bit width, and the ADC uses 1 bit for sampling. Lower power consumption may be achieved in the low precision mode.

Based on the testing device, multi-bit-width fusion may also be implemented. As shown in FIG. 9, which is a schematic diagram of performing multi-bit-width fusion in an embodiment of the disclosure. Assuming that the original single PE has a maximum precision of only 8 bits. Bit-width expansion and fusion are performed through a plurality of PEs, so that computational precision far exceeding 16 bits is thereby achieved. For instance, the 8-bit data in the input vector A is differentially split into low 4-bit data stream dataflow0 L01 and high 4-bit data stream dataflow1 H23, which are divided into two input vectors and input to the systolic array. The 8-bit weight data is split into low 4-bit L01 and high 4-bit H23, which are stored in four PEs. Through the shift and accumulation modules in the PEs, the matrix operation results of LL+HL and LH+HH may be obtained in two output channels. Finally, the shift accumulation of the LL+HL and the LH+HH is executed in the FPGA on the systolic array architecture motherboard tile, and high-precision operation results are thus achieved.

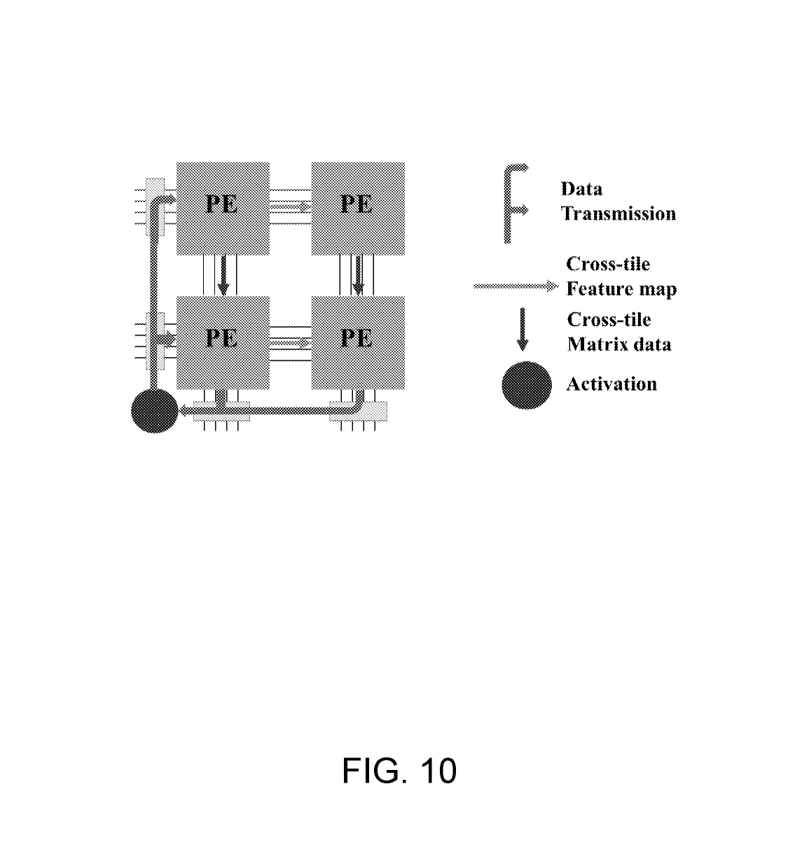

Based on the testing device, acceleration of a neural network may also be achieved. FIG. 10 is a schematic diagram of computational acceleration of a neural network in an embodiment of the disclosure. Feature data is input from the FPGA to the PE. After matrix computational acceleration, the data result is transmitted back to the FPGA to execute various activations, where the activation functions may be implemented by the FPGA. The final processing result is transmitted from the FPGA back to the host computer. The entire process described above achieves acceleration of verification of the systolic array architecture based on the non-volatile memory chip, which may be used for verification and development of neural network chips.

The technical features of the above-described embodiments may be combined in any manner. For the sake of brevity, not all possible combinations of the technical features in the above embodiments are described. However, as long as there is no contradiction in the combinations of these technical features, they should all be considered within the scope recorded in this specification. It should be noted that "in one embodiment", "for example", "as another example", etc. of the disclosure are intended to illustrate the disclosure, rather than to limit the disclosure.

The above-described embodiments merely express several implementation modes of the disclosure, and the descriptions thereof are relatively specific and detailed, but this should not be understood as limiting the scope of the patent claims. It should be noted that for those of ordinary skill in the art, without departing from the concept of the disclosure, several variations and improvements may also be made, and these all fall within the protection scope of the disclosure.

What is claimed is:

1. A flexible systolic in-memory array testing device, comprising:
a sub-board array composed of a plurality of sub-boards, wherein each of the sub-boards comprises a chip socket, a digital-to-analog conversion module, a driving module, a differential readout module, an analog-to-digital conversion module, a shift and accumulation module, and first to fourth bidirectional ports,
the chip socket is configured to be placed with an in-memory array chip that performs a matrix operation with an input vector,
bidirectional transmission of the input vector can be performed between the first bidirectional port and the second bidirectional port of a previous sub-board in a same row and between the first bidirectional port and the second bidirectional port of its own sub-board,
the digital-to-analog conversion module is configured to obtain the input vector from the first bidirectional port and convert it into a voltage signal, and the driving module is configured to connect the voltage signal to the chip and provide a driving current;
bidirectional transmission of a result vector can be performed between the third bidirectional port and the fourth bidirectional port of a foregoing sub-board in a same column and between the third bidirectional port and the shift and accumulation module of itself, and bidirectional transmission of the result vector can be performed between the fourth bidirectional port and the shift and accumulation module,
the differential readout module comprises two inverting amplifier circuits and one adder-subtractor circuit, non-inverting input terminals of the two inverting amplifier circuits sample output currents of two adjacent columns in the chip, inverting input terminals are applied with clamping voltages, output terminals are connected to the adder-subtractor circuit for differential calculation and then perform outputting to the analog-to-digital conversion module for analog-to-digital conversion, and the shift and accumulation module is configured to perform shift accumulation on an analog-to-digital conversion result and a digital signal from the third bidirectional port or the fourth bidirectional port to achieve aggregation and obtain the result vector.

2. The flexible systolic in-memory array testing device according to claim 1, wherein a resistor connected between the inverting input terminal and the output terminal of each of the inverting amplifier circuits is an adjustable resistor.

3. The flexible systolic in-memory array testing device according to claim 1, wherein the clamping voltage applied to each of the inverting amplifier circuit has a value range of 0.4V to 0.6V.

4. The flexible systolic in-memory array testing device according to claim 1, wherein the driving module is a voltage follower constructed by an operational amplifier.

5. The flexible systolic in-memory array testing device according to claim 1, wherein the driving current provided by the driving module is 40mA to 60mA.

6. The flexible systolic in-memory array testing device according to claim 1, wherein the in-memory array chip is a non-volatile memory array chip.

7. The flexible systolic in-memory array testing device according to claim 1, wherein one sub-board can accommodate two chips, and matrix expansion is achieved through the two chips.

8. The flexible systolic in-memory array testing device according to claim 1, wherein the device further comprises an FPGA programmable logic array for implementing data scheduling and control.

9. A control method for a flexible systolic in-memory array testing device, wherein the testing device is the testing device according to claim 1, the control method comprising:
obtaining N groups of input vectors to be input into the sub-board array, wherein one group of input vectors corresponds to one row of sub-boards, and N is the number of rows of the sub-board array;
scheduling and controlling data according to a set systolic direction, wherein the systolic direction comprises a row systolic direction of an input vector between sub-boards in a same row and a column systolic direction of a result vector between sub-boards in a same column, and the scheduling and controlling data comprises:
controlling the input vector to be transmitted sequentially from a previous sub-board to a next sub-board in a pipeline mode in the row systolic direction through the first bidirectional port and the second bidirectional port and controlling the result vector to be transmitted sequentially from a foregoing sub-board to a next following sub-board in a pipeline mode in the column systolic direction through the third bidirectional port and the fourth bidirectional port, wherein transmission time of the input vector between adjacent sub-boards and processing time for the sub-board to receive the input vector and obtain the result vector are both one systolic cycle, and the sub-board acquires a new input vector in each systolic cycle to complete the matrix operation and acquires the result vectors from other sub-boards to perform shift accumulation to obtain a new result vector.

10. The control method according to claim 9, wherein the systolic direction is any one of the following settings:
setting one: the input vector systolically moves rightward, and the result vector moves systolically downward;
setting two: the input vector systolically moves rightward, and the result vector moves systolically upward;
setting three: the input vector systolically moves leftward, and the result vector moves systolically upward; and
setting four: the input vector systolically moves leftward, and the result vector moves systolically downward,
wherein the leftward and rightward are two opposite directions in which rows extend in the sub-board array, and upward and downward are two opposite directions in which columns extend in the sub-board array.
